(19) United States
(12) Patent Application Publication
(10) Pub. No.: US 2009/0134919 A1
(43) Pub. Date: May 28, 2009

(54) Input buffer for high-voltage signal application

(76) Inventors: Cheng-Hung Chen, Jhubei City (TW); Yun-Hsueh Chuang, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/987,031

(22) Filed: Nov. 27, 2007

(51) Int. Cl. H03K 3/00

(52) U.S. Cl. 327/108

(57) ABSTRACT

An input buffer for a high-voltage signal application is provided. The input buffer uses a clamper and an inverter to clamp the output voltage in a proper range even if the input voltage is too high or too low. The proper range of the output voltage is controlled by a voltage source and the ground, so that an electrical device can be triggered safely by the output voltage.

### 1. FIELD OF THE INVENTION

This invention relates to an input buffer, and, more especially, to an input buffer for a high-voltage signal application.

### 2. BACKGROUND OF THE RELATED ART

An electrical device is triggered by an external signal. However, the electrical device may be destroyed if the voltage of the external signal is too high. The input buffer is designed to receive the external signal and transmits a voltage in a proper range to trigger the electrical device safely.

An input buffer for applying to a Schmitt trigger has been developed in prior arts. The input buffer uses a second voltage source different from that of the Schmitt trigger to avoid over stressing the metal oxide silicon field effect transistors (MOSFETs) used in the Schmitt trigger. The input buffer can drive the Schmitt trigger safely. However, it needs two voltage sources, one for input buffer and the other for the electrical device, and is accompanied by a leakage current.

A new input buffer is disclosed here, which can take high-voltage signal and trigger the electrical device safely without the leakage current.

### SUMMARY OF THE INVENTION

It is an object to provide an input buffer for a high-voltage signal application. The input buffer includes a clamper and an inverter. The clamper is connected between a voltage source and the ground, and the inverter is connected between an output and a second input of the clamper, and a first input of the clamper is defined as the input for receiving the external signal. The clamper clamps the output voltage between a highest voltage and a lowest voltage, wherein the highest voltage and the lowest voltage are provided by the voltage source and the ground. Therefore, the connected electrical device can be triggered safely by the output voltage.

### BRIEF DESCRIPTION OF THE DRAWINGS

FIG. 1 is a schematic diagram showing the basic electrical circuit of an input buffer according to an embodiment of this invention.

FIG. 2 is a diagram showing an implemented circuit of an input buffer circuit according to an embodiment shown in FIG. 1.

FIG. 3 is a schematic diagram showing the basic electrical circuit of an input buffer according to another embodiment of this invention.

FIG. 4 is a diagram showing the implemented circuit of a voltage shaper in the embodiment shown in FIG. 3.

### DETAILED DESCRIPTION OF THE INVENTION

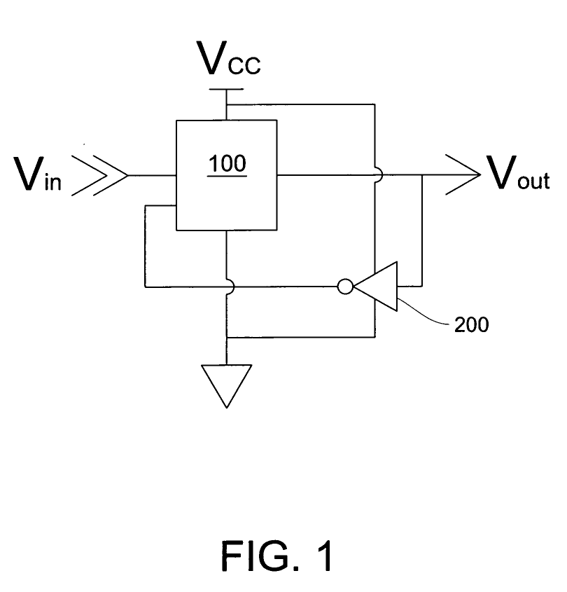

FIG. 1 shows the basic electrical circuit topology of an input buffer according to an embodiment of this invention. The input buffer includes a clamper 100 and an inverter 200. The clamper 100 is connected between a voltage source with voltage V_{CC} and the ground. A first input of the clamper 100 is configured to receive an external signal, which is a voltage signal with voltage Vᵢₙ marked as Vᵢₙ in the figures. The inverter 200 is connected between an output and a second input of the clamper 100. The voltage Vₒᵤₜ on the output of the clamper 100 is clamped, wherein the output voltage is marked as Vₒᵤₜ in figures.

The output voltage Vₒᵤₜ of the clamper 100 is proportional to the input voltage Vᵢₙ but clamped under the voltage V_{CC}, that is the maximum of the output voltage Vₒᵤₜ is equal to the voltage V_{CC}. When the input voltage Vᵢₙ is non-positive, the inverter will pull the output voltage Vₒᵤₜ down to the ground voltage, that is, the output voltage Vₒᵤₜ is clamped at the ground voltage by the inverter 200. Because the output voltage Vₒᵤₜ is clamped between voltage V_{CC} and the ground voltage, the input buffer can trigger safely an electrical device connected to the input buffer.

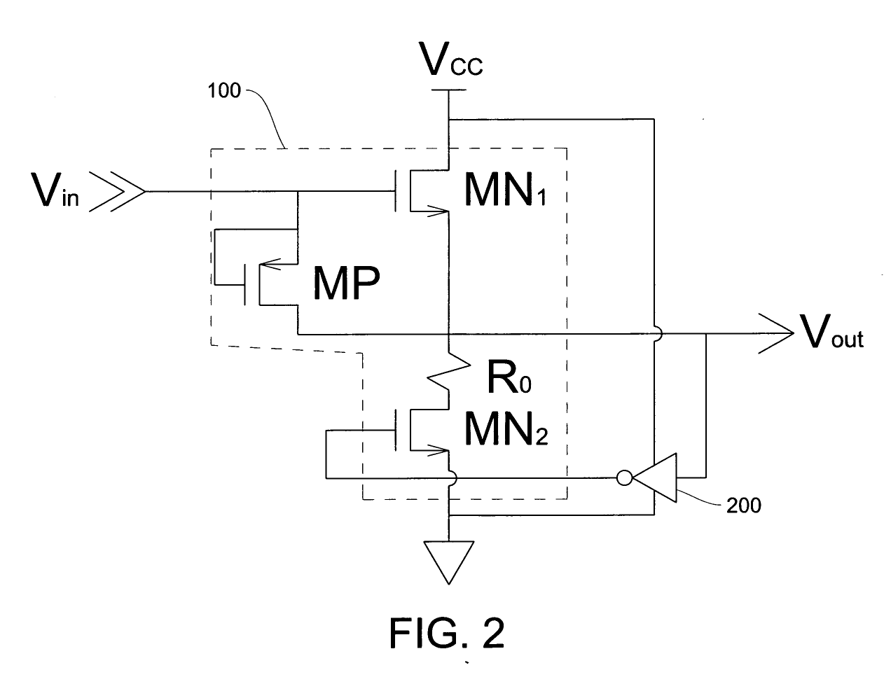

FIG. 2 shows an electrical circuit implementing the input buffer shown in FIG. 1. The clamper 100 includes a first n-channel metal oxide silicon field effect transistor (hereafter denoted as NMOS) MN₁, a second NMOS MN₂, a resister R and a p-channel metal oxide silicon field effect transistor (hereafter denoted PMOS) MP, wherein the resister R and the PMOS MP can be omitted. The drain electrode of the first NMOS MN₁ is connected to the voltage source with voltage V_{CC}. The gate electrode and the source electrode of the PMOS MP are coupled to form a diode connected PMOS, and connected to the gate electrode of the first NMOS MN₁, and the drain electrode is connected to the source electrode of the first NMOS MN₁. The resister R is connected between the source electrode of the first NMOS MN₁ and the drain electrode of the second NMOS MN₂. The source electrode of the second NMOS MN₂ is connected to the ground. The input and output of the inverter 200 are connected to the source electrode of the NMOS MN₁ and the gate electrode of the NMOS MN₂.

According to the abovementioned, the diode-connected PMOS can be replaced by a diode or a diode-connected NMOS. When the diode-connected NMOS is used, the source electrode and the gate electrode of the diode-connected NMOS are coupled and connected to the source electrode of the first NMOS, and the drain electrode of the diode-connected NMOS is connected to the input of said clamper. Or, when a diode is used, the cathode of said diode is connected to said input of said clamper, and the anode of said diode is connected to the source electrode of said first NMOS.

The diode-connected PMOS, diode-connected NMOS or diode are used to enhance the performance of the input buffer, so that the diode-connected PMOS, diode-connected NMOS or diode can be omitted when the performance is not the issue.

The gate electrode of the first NMOS MN₁ is defined as the input of the clamper 100 to receive the input voltage Vᵢₙ, and the source electrode is defined as the output of the clamper 100 to transmit the output voltage Vₒᵤₜ. The gate electrode of the second NMOS MN₂ is defined as the second input of the clamper 100.

For positive input voltage Vᵢₙ, the first NMOS MN₁ is turned on and the output voltage Vₒᵤₜ is proportional to the input voltage Vᵢₙ when the input voltage Vᵢₙ is smaller than a threshold voltage, and the output voltage Vₒᵤₜ keeps at the voltage V_{CC} when input voltage Vᵢₙ is getting higher than the threshold voltage. In the meanwhile, the inverter 200 inverts the positive output voltage Vₒᵤₜ to a negative voltage to turn off the second NMOS MN₂.

For negative input voltage Vᵢₙ, the first NMOS MN₁ is turned off, and the PMOS MP quickly pulls down the output voltage Vₒᵤₜ. In the meanwhile, the inverter 200 inverts the output voltage Vₒᵤₜ to a positive voltage to turn on the second NMOS MN₂. As a result, the output voltage Vₒᵤₜ is fixed at the ground voltage. Therefore, the input buffer clamps the output voltage Vₒᵤₜ between the voltage V_{CC} and the ground voltage even if the input voltage Vᵢₙ is too high or too low.

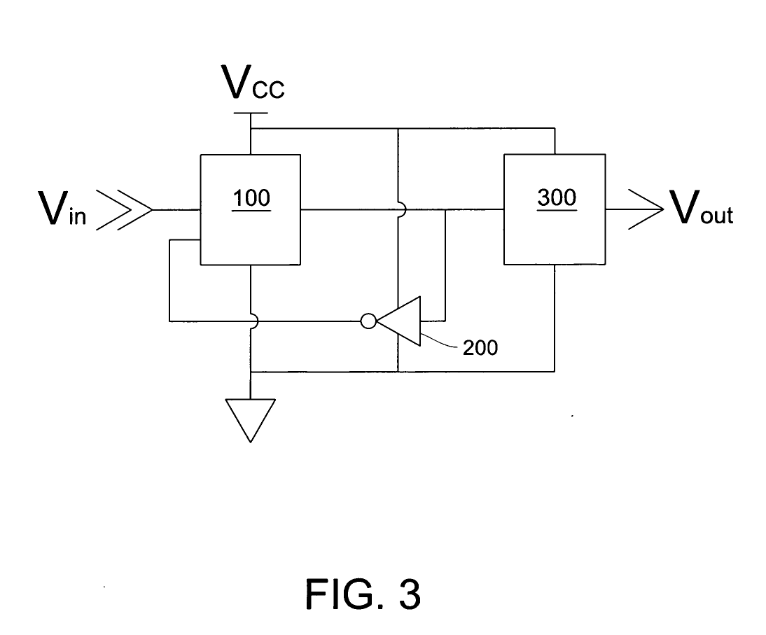

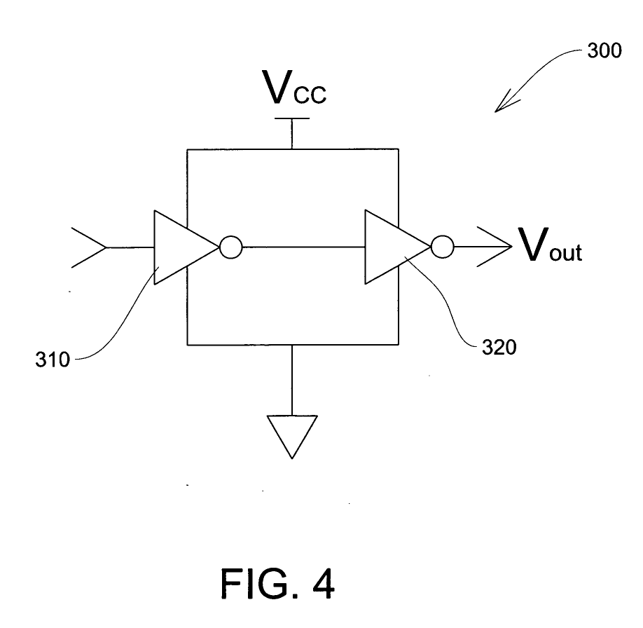

FIG. 3 shows an input buffer circuit topology according to another embodiment of this invention. Comparing this embodiment with that in FIG. 1, the difference is the additional voltage shaper 300 connected to the clamper 100 in this embodiment. The voltage shaper 300 can shape the output voltage Vₒᵤₜ to a square waveform. FIG. 4 shows a circuit implementing the shaper in the embodiment shown in FIG. 3. The shaper 300 includes two serial-connected inverters 310, 320. The first inverter 310 inverts the phase of the output voltage Vₒᵤₜ, so the second inverter 320 inverts it again to restore the phase of the output voltage Vₒᵤₜ.

Accordingly, the input buffer uses a clamper and an inverter to isolate the input voltage from the electrical components of a device connected to the input buffer, and transmits an output voltage in a proper range controlled by the voltage source and the ground. As a result, the input voltage cannot over stress the electrical components of the device. Additionally, the voltage source cannot form a circuit loop to the input of the clamper or the ground, so that there is no leakage current.

Although the present invention has been explained in relation to its preferred embodiment, it is to be understood that modifications and variation can be made without departing the spirit and scope of the invention as claimed.

What is claimed is:

1. An input buffer, applied to a high-voltage application, comprising:
a clamper electrically connected to an voltage source and the ground, wherein said clamper has a first input, a second input and an output; and
an inverter connected between said output and said second input of said clamper.

2. An input buffer according to claim 1, wherein said clamper comprises:
a first NMOS, wherein a drain electrode of said first NMOS is connected to said voltage source, and a gate electrode of said first NMOS to is defined as said first input of said clamper; and
a second NMOS, wherein a drain electrode of said second NMOS is connected to the source electrode of said first NMOS, and a gate electrode of said second NMOS is defined as said second input, and a source electrode of said second NMOS is connected to the ground.

3. An input buffer according to claim 2, wherein said clamper further comprises a resister, and said resister is connected between the source electrode of said first NMOS and the drain electrode of said second NMOS.

4. An input buffer according to claim 2, wherein said clamper further comprises a PMOS, and a source electrode and a gate electrode of said PMOS are coupled and connected to said input of said clamper, and a drain electrode of said PMOS is connected to the source electrode of said first NMOS.

5. An input buffer according to claim 2, wherein said clamper further comprises a third NMOS, and a source electrode and a gate electrode of said third NMOS are coupled and connected to the source electrode of said first NMOS, and a drain electrode of said third NMOS is connected to said input of said clamper.

6. An input buffer according to claim 2, wherein said clamper further comprises a diode, and the cathode of said diode is connected to said input of said clamper, and the anode of said diode is connected to the source electrode of said first NMOS.

7. An input buffer according to claim 1, wherein said clamper further comprises a voltage shaper for shaping the voltage waveform of the output voltage of said clamper.

8. An input buffer according to claim 7, wherein said voltage shaper comprises two serial-connected inverters.

9. An input buffer according to claim 7, wherein said clamper comprises:
a first NMOS, wherein a drain electrode of said first NMOS is connected to said voltage source, and a gate electrode of said first NMOS to is defined as said first input of said clamper; and
a second NMOS, wherein a drain electrode of said second NMOS is connected to the source electrode of said first NMOS, and a gate electrode of said second NMOS is defined as said second input, and a source electrode of said second NMOS is connected to the ground.

10. An input buffer according to claim 9, wherein said clamper further comprises a resister, and said resister is connected between a source electrode of said first NMOS and a drain electrode of said second NMOS.

11. An input buffer according to claim 9, wherein said clamper further comprises a PMOS, and a source electrode and a gate electrode of said PMOS are coupled and connected to said input of said clamper, and a drain electrode of said PMOS is connected to the source electrode of said first NMOS.

12. An input buffer according to claim 9, wherein said clamper further comprises a third NMOS, and a source electrode and a gate electrode of said third NMOS are coupled and connected to the source electrode of said first NMOS, and a drain electrode of said third NMOS is connected to said input of said clamper.

13. An input buffer according to claim 9, wherein said clamper further comprises a diode, and the cathode of said diode is connected to said input of said clamper, and the anode of said diode is connected to the source electrode of said first NMOS.
